(19) United States
(12) Patent Application Publication
(10) Pub. No.: US 2012/0227667 A1
(43) Pub. Date: Sep. 13, 2012

(54) SUBSTRATE CARRIER WITH MULTIPLE EMISSIVITY COEFFICIENTS FOR THIN FILM PROCESSING

(75) Inventors: Juno Yu-Ting HUANG, Santa Clara, CA (US); Suresh M. SHRAUTI, Palo Alto, CA (US); Alain DUBOUST, Sunnyvale, CA (US); David BOUR, Cupertino, CA (US); Wei-Yung HSU, San Jose, CA (US); Liang-Yun CHEN, Foster City, CA (US)

(73) Assignee: APPLIED MATERIALS, INC., Santa Clara, CA (US)

(21) Appl. No.: 13/413,002

(22) Filed: Mar. 6, 2012

Related U.S. Application Data
(60) Provisional application No. 61/451,534, filed on Mar. 10, 2011.

(51) Int. Cl. C30B 25/12; B05D 5/00; B24B 1/00; C30B 25/02

(52) U.S. Cl. 118/728; 118/500; 427/256; 451/28

(57) ABSTRACT

Substrate carrier having multiple emissivity coefficients for thin film processing and more particularly for support of a substrate during a deposition process epitaxially growing a film on the substrate. A front side of the carrier has a first carrier surface upon which the substrate is to be disposed, the first carrier surface having a first emissivity coefficient different than a second emissivity coefficient of a second carrier surface adjacent to the first carrier surface. Selection of the second emissivity coefficient independent of the first emissivity coefficient may modify an amount of energy radiated from the second carrier surface during processing of the substrate. In one embodiment, the second carrier surface has a second emissivity coefficient which is lower than the first emissivity coefficient to reduce heat loss from the carrier surface while maintaining high efficiency energy transfer between the carrier and a substrate.

### CROSS REFERENCE TO RELATED APPLICATIONS

This application claims the benefit of U.S. Provisional Application No. 61/451,534 (Attorney Docket No. 015625L/NEON/ESONG) filed on Mar. 10, 2011, entitled “SUBSTRATE CARRIER WITH MULTIPLE EMISSIVITY COEFFICIENTS FOR THIN FILM PROCESSING,” the entire contents of which are hereby incorporated by reference in its entirety for all purposes.

### BACKGROUND

1. Field

Embodiments of the present invention pertain to the field of thin film epitaxial growth, and more particularly to carriers for supporting substrates during epitaxial growth of thin films.

2. Description of Related Art

Group III-V materials are playing an ever increasing role in the semiconductor and related, e.g. light-emitting diode (LED), industries. While LEDs employing multiple quantum well (MQW) structures epitaxially grown on a substrate are a promising technology, epitaxial growth of such structures is difficult because epitaxial growths are often very sensitive to the temperatures of the substrate and various components within a deposition chamber.

Many deposition systems employed to perform the epitaxial thin film growths, utilize a carrier to support one or more substrates during film growth. The carrier dimensions can be quite large (e.g., 300 mm) depending on the diameter of the substrate and number of substrates supported at any given time. The carrier is often heated, for example by way of heat lamps, resistive, and inductive heaters, disposed below a bottom surface of the carrier while the substrates are positioned on a top surface of the carrier. In additional to heating the substrates to a proper growth temperature, the heated carrier may further radiate heat to other portions of the deposition chamber, for example a gas showerhead, which is often maintained at a temperature below that of the substrate and/or carrier. Depending on the growth processes performed by the chamber, changes in the amount of heat radiated by the carrier to chamber components like the showerhead may induce variation in heating efficiency supplied to the substrates and the properties of the films grown on the substrates, either within a single growth (i.e., process run) or across multiple growths (i.e., run-to-run).

A carrier engineered to prevent heat radiation within the chamber from the carrier where no wafer is present and to enhance efficiency of substrate heating, as described herein, is therefore advantageous.

### BRIEF DESCRIPTION OF THE DRAWINGS

Embodiments of the present invention is illustrated by way of example, and not by way of limitation, in the figures of the accompanying drawings, in which:

FIG. 1 illustrates a cross-sectional view of a GaN-based LED film stack which may be grown using a carrier having regions with differing emissivity coefficients, in accordance with an embodiment of the present invention;

FIG. 2A illustrates a isometric view of carrier having regions with differing emissivity coefficients, in accordance with an embodiment of the present invention;

FIG. 2B illustrates a plan view of a top side of a carrier having regions with differing emissivity coefficients, in accordance with an embodiment of the present invention;

FIGS. 2C and 2D illustrate plan views of a backside of the carrier illustrated in FIGS. 2A and 2B, in accordance with embodiments of the present invention;

FIG. 2E illustrates an expanded cross-section view along the A-A′ line illustrated in FIG. 2B, in accordance with an embodiment of the present invention;

FIG. 2F illustrates an expanded plan view of a one pocket in a carrier having regions with differing emissivity coefficients, in accordance with an embodiment of the present invention;

FIG. 3 is a flow diagram illustrating a methods for forming a carrier having regions with differing emissivity coefficients, in accordance with an embodiment of the present invention;

FIG. 4 is a schematic cross-sectional view of an MOCVD apparatus which may incorporate a carrier having regions with differing emissivity coefficients, in accordance with an embodiment of the present invention; and

FIG. 5 is a schematic cross-sectional view of an HVPE apparatus which may incorporate a carrier having regions with differing emissivity coefficients, in accordance with an embodiment of the present invention.

### SUMMARY

Substrate carrier for support of a substrate during a deposition process and having multiple emissivity coefficients is described. A front side of the carrier has a first carrier surface upon which the substrate is to be disposed. The first carrier surface has at least a first emissivity coefficient different than a second emissivity coefficient of a second carrier surface on the front side of the carrier and adjacent to the first carrier surface. Selection of the second emissivity coefficient independent of the first emissivity coefficient may modify an amount of energy radiated from the second carrier surface during processing of the substrate. In one embodiment, the second carrier surface has a second emissivity coefficient which is lower than the first emissivity coefficient. The backside of the carrier may further be with a high emissivity material or high emissivity treatment to enhance the heat source transferring to the carrier.

In an embodiment, light-emitting diodes (LEDs) and related devices may be fabricated from layers of group III-V films while the substrate is disposed on the carrier described herein. Exemplary embodiments of the present invention relate to the growth of group III-V materials with particular embodiments illustrating application to group III-nitride films, such as, but not limited to gallium nitride (GaN) films. Growth of group III-V materials, such as indium gallium nitride, may be made more consistent by improving control of substrate surface temperatures which are dependent on amount of energy radiated from the carrier. Increasing the emissivity on the carrier pocket (the first emissivity) may lead to an enhanced of the heating efficiency from carrier to the wafer. Therefore, the wafer surface processing temperature could be increased at a given power of the heat supply, for example. Minimizing heat power to reach a given temperature is very important for larger scale processes (e.g., substrates>4-inch) and for silicon-substrate process (e.g., GaN on silicon). Reducing emissivity of second regions outside of where substrate is disposed during processing may reduce energy radiated from the carrier and further reduce variation in radiated energy levels from run to run as the second regions of the carrier become covered with byproducts of the deposition process. Increasing emissivity of a backside of a carrier would result in higher efficiency in heat source energy transferring to the whole carrier and the wafer substrates.

In embodiments, either or both of the first and second regions may comprise a material other than the bulk material. In embodiments, surface roughness between the first and second regions of a substrate carrier may be different to vary the emissivity coefficients between the first and second regions. Embodiments include a deposition chamber incorporating the carrier as described herein. In one embodiment a deposition chamber is configured to introduce group III source gases and a nitrogen source gas, such as NH₃, into the deposition chamber to epitaxially grow a group III-nitride on a substrate. Embodiments include methods for processing a bulk material to provide a carrier with multiple emissivity coefficients.

### DETAILED DESCRIPTION

In the following description, numerous details are set forth. It will be apparent, however, to one skilled in the art, that the present invention may be practiced without these specific details. In some instances, well-known methods and devices are shown in block diagram form, rather than in detail, to avoid obscuring the present invention. Reference throughout this specification to “an embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

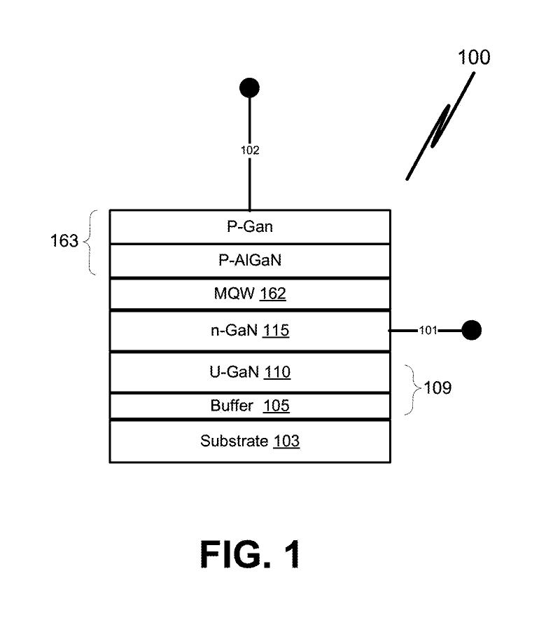

FIG. 1 illustrates a cross-sectional view of a GaN-based LED film stack which may be grown on a substrate supported by a carrier having regions with differing emissivity coefficients, in accordance with an embodiment of the present invention. While a GaN-based LED film stack is presented herein as an exemplary application, other applications may also take similar benefit from the carrier embodiments described herein. For example, in growth technologies such as GaN on silicon devices for HEMT and other high speed, high power devices may also employ carriers as described herein.

Depending on the embodiment, layers in a III-V LED stack, such as that in the LED 100 depicted in FIG. 1A, are grown with a single chamber process or a multiple chamber process. For a single chamber process, layers of differing composition are grown successively as different steps of a growth recipe executed within the single chamber. For a multiple chamber process, layers are grown in a sequence employing separate chambers. For example, and undoped and/or an nGaN layer may be grown in a first chamber, a MQW structure in a second chamber, and a pGaN layer grown in a third chamber.

In FIG. 1A, an LED stack is formed on a substrate 103. In one implementation, the substrate 103 is single crystalline sapphire (e.g., (0001)) and may be patterned or unpatterned. Other embodiments contemplated include the use of substrates other than sapphire substrates, such as, Silicon (Si), germanium (Ge), silicon carbide (SiC), gallium arsenide (GaAs), zinc oxide (ZnO), lithium aluminum oxide (γ-LiAlO₂).

Upon the substrate 103, are one or more support layers for a p-n junction formed thereon. A transition or buffer layer 105 is formed on the substrate to facilitate transition of crystallographic and thermal properties between the substrate 103 and the LED device layers. The buffer layer 105 is generally to be of a material which includes crystalline nuclei domains within amorphous regions. Exemplary buffer materials include group III-nitride based materials, such as, but not limited to, GaN, InGaN, AlGaN, and AN. Exemplary thicknesses of the buffer layer 105 are in the range of 10 nm to 200 nm depending on the material with one GaN buffer embodiment being in the range of 10 nm to 20 nm.

As further illustrated in FIG. 1A, the LED stack includes an undoped layer 110 disposed over the buffer layer 105 to form a base layer stack 109. The undoped layer 110 is to be of a good quality and substantially single crystalline, as epitaxially grown from the crystalline nuclei domains in the buffer layer 105, with as low of defect density as possible so that the LED device layers disposed over the undoped layer may also be of a lowest possible defect density to provide a high quantum efficiency.

One or more bottom n-type epitaxial layer 115 is further included in the LED stack incorporated into the LED 100. In the exemplary group III-nitride material system, the bottom n-type epitaxial layer 115 may be any n-type group III-nitride based material, such as, but not limited to, GaN, InGaN, AlGaN.

Disposed on the bottom n-type epitaxial layer 115 is a multiple quantum well (MQW) structure 162. The MQW structure 162 may be any known in the art to provide a particular emission wavelength. In a certain embodiments, the MQW structure 162 may have a wide range of indium (In) content within GaN. For example, depending on the desired wavelength(s), the MQW structure 162 may have between about a 10% to over 40% of mole fraction indium as a function of growth temperature, ratio of indium to gallium precursor, etc. It should also be appreciated that any of the MQW structures described herein may also take the form of single quantum wells (SQW) or double hetereostructures that are characterized by greater thicknesses than a QW. The MQW structure 162 may be grown in a metalorganic chemical vapor deposition (MOCVD) chamber or a hydride/halide vapor phase epitaxy (HVPE) chamber, molecular beam epitaxy (MBE), liquid phase epitaxy (LPE), or another known in the art. Any growth techniques known in the art may be utilized with such chambers.

One or more p-type epitaxial layers 163 are disposed over the MQW structure 162. The p-type epitaxial layers 163 may include one or more layers of differing material composition. In the exemplary embodiment depicted in FIG. 1, the p-type epitaxial layers 163 include both p-type GaN and p-type AlGaN layers doped with Mg. In other embodiments only one of these, such as p-type GaN are utilized. Other materials known in the art to be applicable to p-type contact layers for GaN systems may also be utilized. The thicknesses of the p-type epitaxial layers 163 may also vary within the limits known in the art. Like the MQW structure 162, the p-type epitaxial layers 163 may also be gown in an MOCVD, HYPE, MBE, or LPE epitaxy chamber. Incorporation of Mg during the growth of the p-type epitaxial layers 163 may be by way of introduction of cp₂Mg to the epitaxy chamber, for example. In an embodiment, the p-type epitaxial layers 163 are grown using the same epitaxial chamber as the MQW structure 162.

Additional layers (not depicted), such as, tunneling layers, n-type current spreading layers and further MQW structures (e.g., for stacked diode embodiments) may be disposed over the p-type epitaxial layers 163 in substantially the same manner described for the layers illustrated in the exemplary LED 100 or in any manner known in the art. Following the growth of the LED stack, conventional patterning and etching techniques are performed to expose regions of the bottom n-type epitaxial layer 115 and the p-type epitaxial layer(s) 163. Any contact metallization known in the art may then be applied to the exposed regions to form an n-type terminal 101 and a p-type terminal 102. In exemplary embodiments, the n-type terminal includes a contact, such as, but not limited to, Al/Au, Ti/Al/Ni/Au, Al/Pt/Au, or Ti/Al/Pt/Au. An exemplary p-type terminal includes a Ni/Au or Pd/Au contact. For either n-type or p-type contacts, a transparent conductor, such as Indium Tin Oxide (ITO), or others known in the art, may also be utilized.

One or more of the layers in the LED 100 may be subject to dopant incorporation efficiency variation and indium incorporation efficiency variation due to temperature variations while the layer is grown. For example, it has been found that indium incorporation efficiency variation is at least partially attributable to showerhead temperature and/or the chamber temperature inconsistency (e.g., drift of temperature from run-to-run). Such inconsistency of indium incorporation efficiency during growth of the MQW structure 162, for example, may lead to emission wavelength drift from run-to-run.

Substrate carriers made of silicon carbide (SiC) have high emissivity coefficient (ε) and high thermal conductivity. In comparison with SiC, a sapphire substrate 103 has low emissivity coefficient and low thermal conductivity. Due to the low emissivity of the substrate 103, carrier temperature can have non-uniform (i.e., a cold spot) proximate to the substrate). For such a carrier/substrate material combination, most of the heat and radiant energy from the carrier will transfer to nearby chamber components, such as a gas showerhead disposed above the carrier, via the regions of the carrier not covered by a substrate 103. While high carrier emissivity coefficient is beneficial in regions disposed below a substrate for heating of the substrate 103 by the carrier, it is advantageous to reduce energy transferred from the carrier to the gas showerhead. A gas showerhead is usually cooled to a temperature of about 30° C.-300° C. below that of the substrate (heated to 900° C.-1300° C., or more, by the carrier which is heated from a backside, for example by lamps disposed below the carrier).

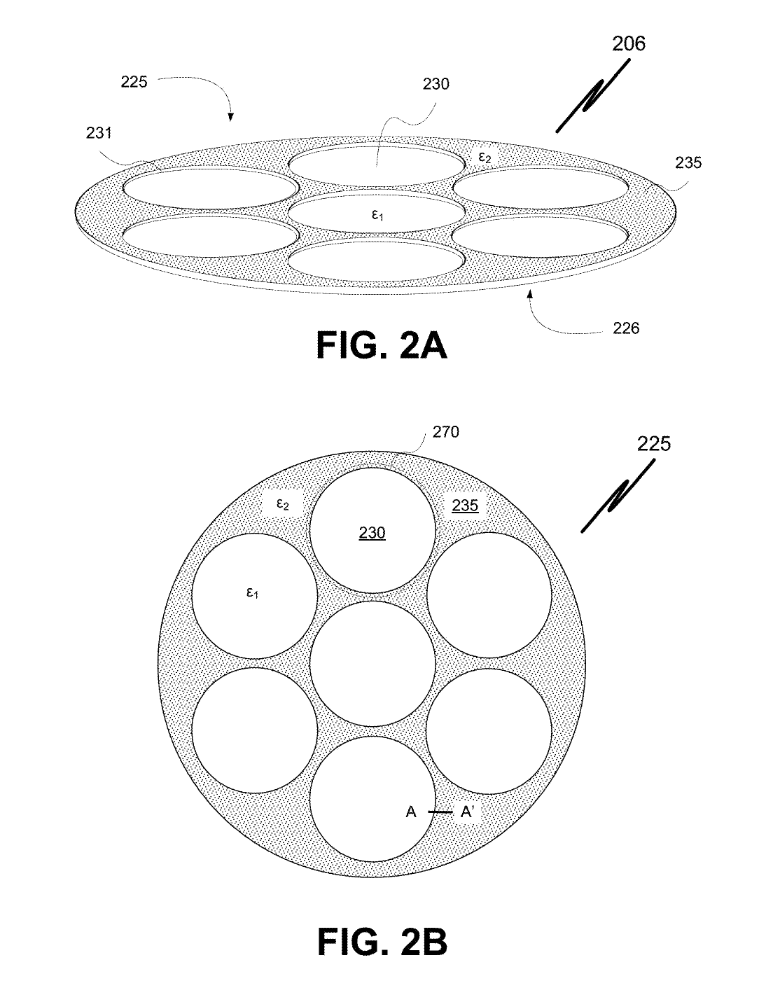

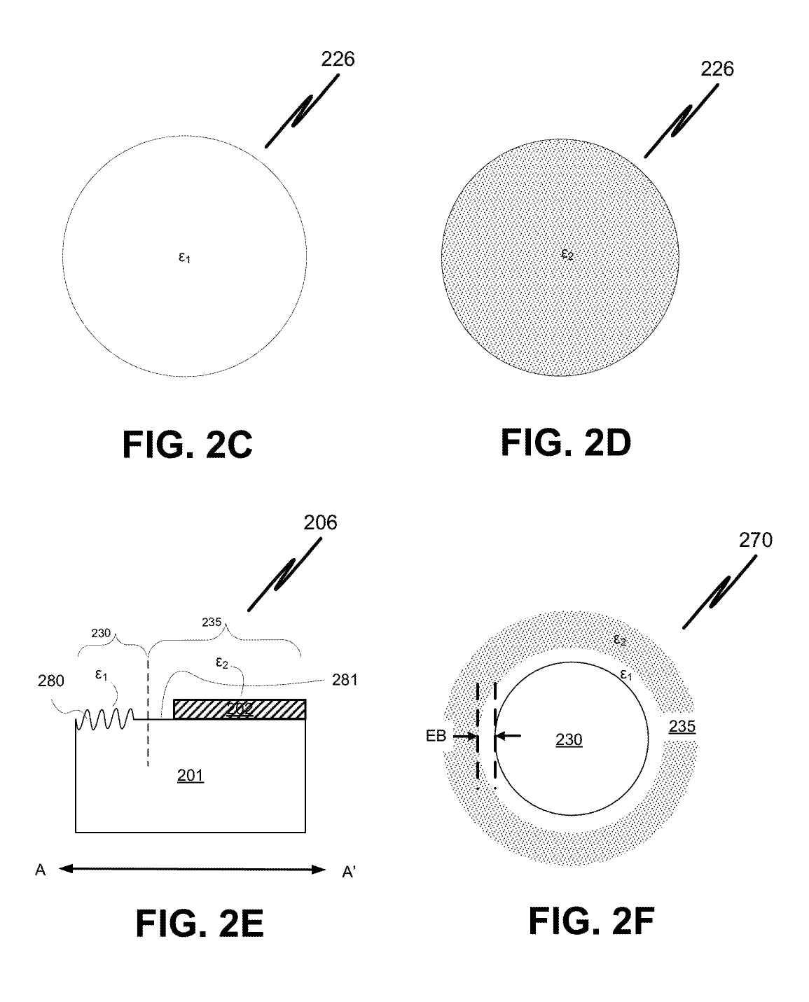

FIG. 2A illustrates an isometric view of a carrier having regions with differing emissivity coefficients, in accordance with an embodiment of the present invention. Generally, the differing emissivity coefficients are to decouple carrier radiation rates to the substrate from carrier radiation rates to various deposition chamber components. First regions where the substrate is to be disposed have a first emissivity coefficient and second regions where no substrate is to be disposed have a second, different, emissivity coefficient. In certain embodiments, a gradient of radiant heat from the carrier to the showerhead may be decreased by matching the carrier emissivity of the second regions to the substrate emissivity. Chamber temperature uniformity may then be improved for improved within run and run-to-run repeatability.

In certain exemplary embodiments, control of dopant and compound semiconductor element incorporations during a LED and high power device stack growths (e.g., growth of MQW structure 162) may be improved through improved temperature uniformity across the substrate, carrier and chamber afforded by making carrier emissivity a function of carrier area. Carrier areas with a lower emissivity (the second emissivity) act to reduce energy transfer from the carrier to a showerhead disposed over the carrier and to improve heating efficiency on areas of the carrier with higher emissivity area (the first emissivity). The first emissivity is preferably greater than the second emissivity. It is noted, however, that the opposite effect could also be achieved using the principals described herein.

Referring to FIG. 2A, carrier 206 includes a front side 225 and a backside 226. On the front side 225 are one or more carrier regions 230 upon which a substrate (e.g., substrate 103) is to be disposed during a deposition process. Surrounding region 235 is adjacent to the carrier regions 230 and is to remain uncovered by any substrate during processing. In the exemplary embodiment, the surface of carrier regions 230 is recessed below the surface of region 235 to for a pocket having sidewall 231 inside of which a substrate is to be seated. The design of pocket where the substrate sits can vary as a matter of design choice with. Depending on the size of the substrates, one or more carrier regions 230 may be present on the carrier 206 (e.g., seven substrate pockets are depicted in FIG. 2A). As shown, carrier regions 230 have a first emissivity coefficient ε₁ while surrounding region 235 has a second emissivity coefficient ε₂. For the exemplary substrate carrier directed at LED or laser layer growths or high power devices on a GaN on Si substrate, the second emissivity coefficient ε₂ is lower than first emissivity coefficient ε₁.

While the first and second emissivity coefficients can vary depending on the implementation, the difference between the first and second emissivity coefficients should be at least 0.2. This relative difference in emissivity is to be as measured at a same reference temperature since emissivity is a function of temperature. In particular embodiments, the difference between the first and second emissivity coefficients is much larger than 0.2, for example, a difference of 0.6-0.8 is achieved particular embodiments with the difference dependent on the materials and/or machining of the carrier regions 230 and surrounding region 235 as further described elsewhere herein.

FIG. 2B illustrates a plan view of the carrier front side 225, in accordance with an embodiment of the present invention while FIGS. 2C and 2D illustrate plan views of the carrier backside 226 of the carrier 206, in accordance with embodiments of the present invention. Generally, the carrier backside may have a third emissivity coefficient ε₃, which may be equal to the first emissivity coefficient ε₁ (as shown in FIG. 2C), equal to the second emissivity coefficient ε₂ (as shown in FIG. 2D), or different than both ε₁ and ε₂. For the exemplary substrate carrier directed at LED layer growths, the carrier backside emissivity coefficient ε₃ is high, for example equal to the first emissivity coefficient ε₁.

FIG. 2E illustrates an expanded cross-section view of the carrier 206 along the A-A′ line illustrated in FIG. 2B, in accordance with embodiments of the present invention. Various features depicted in FIG. 2B may be employed in combination or individually. In one embodiment shown, the carrier region 230 has a surface roughness (e.g., RMS roughness) 280 which is greater than the surface roughness 281 in the surround region 235. This difference in roughness may be the sole basis for the different emissivity coefficients ε₁ and ε₂, or may only be a contribution toward a total emissivity difference between the two regions 230 and 235. For example, in one embodiment where the carrier region 230 comprises a same material on the surface as does the surrounding region 235, then the difference in emissivity coefficients ε₁ and ε₂ results from the different surface roughness 280, 281. As illustrated in FIG. 2E, both the carrier region 230 and the surrounding region 235 comprise the bulk material 201, which may be for example silicon carbide. For such an embodiment, a high polish on the surrounding region 235 and/or deliberate roughening of the region 230 provides the emissivity delta.

In another embodiment, the region 230 is a different material than is the surrounding region 235. In the exemplary embodiment shown in FIG. 2C, the carrier 206 comprises a bulk material 201 and the region 230 is a surface of the bulk material 201 while the surrounding region 235 comprises a coating 202 disposed over the bulk material 201. For one such embodiment where the bulk material 201 has a high emissivity coefficient, the coating 202 has a lower emissivity coefficient than the bulk material 201.

The coating 202 may comprise a variety of materials selected for the desired emissivity coefficient in view of the need for material stability at substrate processing temperatures (e.g., 900-1300° C.). Differences in the coefficient of thermal expansion (CTE) between the bulk material 201 and the coating 202 are preferably minimized to reduce stress induced delamination of the coating 202 as the carrier 206 is thermally cycled during processing. Given these constraints, the coating 202 may be one of many materials having an emissivity coefficient less than or equal to about 0.7 at 1100° C. In an embodiment, the coating 202 is of a material other than what is to be formed during the deposition process performed on the substrate (e.g., other than group III-V materials). For example, if GaN is to be grown on the substrate, as in the case for the LED 100, the coating 202 is other than GaN (i.e., the coating 202 is more than a pre-coating of the carrier). Exemplary materials for the coating 202, include, but are not limited to ceramic materials, cerium oxide, zirconium oxide, mullite (Al₆Si₂O₁₃), macor (fluorphlogopite mica in a borosilicate glass matrix), polished tungsten, nickel-chromium (Ni—Cr), nickel-chromium-iron (Ni—Cr—Fe), polished molybdenum, and aluminum oxide. These materials may be further doped with additives to improve CTE match with the bulk material 201. For example, zirconium oxide may be doped with one or more of MgO, CaO, or Y₂O₃. In addition, the plasma-spray porous coatings or thermal coatings such as RLHY-12 could be also applied at the lower emissivity coefficient area (ε₂) to prevent heat loss and thermal radiation.

For any embodiment employing the coating 202, the bulk material may comprise SiC, graphite, molybdenum, tungsten, or similar materials known in the art to be suitable as carriers. FIG. 2E further illustrates the particular embodiment, where the carrier region 230 comprises the bulk material 201 (e.g., SiC), however in other embodiments the carrier region 230 may have a second coating material (not depicted) disposed over the bulk material 201 substantially as shown for coating 202. For such embodiments, the second material is to have a higher emissivity coefficient than that of the bulk material. Here too, exemplary materials are also to have a CTE approximately equal to that of the carrier bulk material, and be thermally stable at substrate processing temperatures.

FIG. 2E provides an expanded plan view 270 of a one pocket in the carrier 206, in accordance with an embodiment of the present invention. Depending on the embodiment, the surrounding region 235 may be disposed a distance EB from an out perimeter edge bead of the carrier region 230 where a substrate is to be disposed. For embodiments with recessed carrier region 230, the distance EB is measured from the sidewall 231. The distance EB is to reduce the risk of the surrounding region 235 contaminating a substrate, for example where the surrounding region 235 comprises the coating 202. The distance EB may be for example 2 mm or more to leave margin for thermal expansion and/or reduce contamination from coating 202 to substrate.

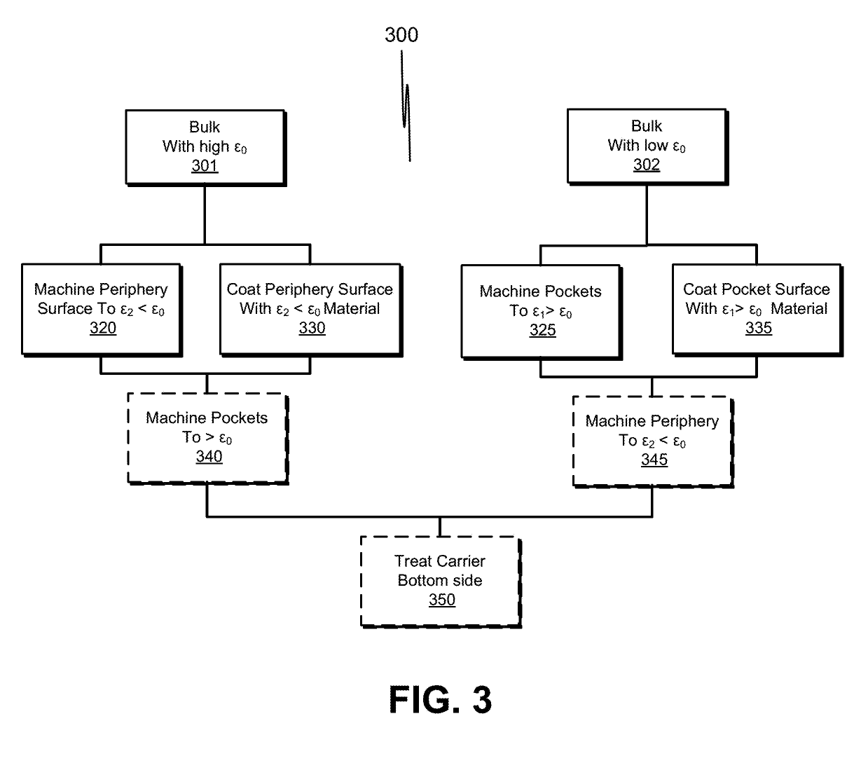

FIG. 3 is a flow diagram illustrating a method 300 for forming a carrier having regions with differing emissivity coefficients, in accordance with an embodiment of the present invention. Generally, a bulk material is processed to have a first emissivity coefficient in a first region upon which the substrate is to be disposed and a second emissivity, lower than the first emissivity coefficient, in a second region. Depending on the bulk material employed, such processing can take many forms. For example, a bulk may be processed in both the first and second regions to modify the emissivity coefficients as desired. Alternatively, one of the first and second regions may be processed to modify the emissivity coefficient from bulk while the other of the first and second regions retains a bulk emissivity coefficient. As shown in FIG. 3, beginning with a bulk material having a relatively high emissivity ε₀, such as SiC, at operation 301, the periphery (e.g., surrounding region 235) is machined at operation 320 to lower the emissivity coefficient to ε₂<ε₀. For example, in one embodiment, a polishing process is performed on the surrounding region 235 with the substrate pocket remaining unpolished bulk material. Alternatively, or in addition, at operation 330 the periphery (e.g., surrounding region 235) is coated with a coating material having an emissivity coefficient below that of the bulk (ε₂<ε₀) to further reduce the emissivity coefficient. Any of the coating materials described elsewhere herein may be applied at operation 330. Following operation 320 and/or operation 330, the carrier regions 230 may further be machined to enhance the emissivity above that of the bulk material (ε₁>ε₀) at operation 340. For example, micro abrasion techniques known in the art (bead or CO₂ blasting, etc.) may be performed to increase the roughness of the regions upon which a substrate is to be disposed during processing. Method 300 then ends with the carrier backside being treated at operation 350 to have the desired emissivity. In the exemplary embodiments where a high emissivity is desired, no backside treatment need be performed since the bulk material had a relatively high emissivity ε₀.

As further shown in FIG. 3, beginning with a bulk material having a relatively low emissivity ε₀, such as SiC, at operation 302, the substrate pocket (e.g., carrier region 230) is machined at operation 325 to increase the emissivity coefficient to ε₁>ε₀. For example, micro abrasion techniques known in the art (bead or CO₂ blasting, etc.) may be performed to increase the roughness of the regions upon which a substrate is to be disposed during processing. In one such embodiment, a micro abrasion process is performed on the region 230 with the surrounding region 235 remaining non-abraded bulk material. Alternatively, or in addition, at operation 335 the pocket (e.g., carrier region 230) is coated with a coating material having an emissivity coefficient above that of the bulk (ε₁>ε₀) to further increase the emissivity coefficient. Any of the coating materials described elsewhere herein may be applied at operation 330. Following operation 325 and/or operation 335, the surrounding regions 235 may further be machined at operation 345 to reduce the emissivity below that of the bulk material (ε₂<ε₀). For example, polishing or lapping techniques known in the art may be performed to reduce the roughness of the periphery regions where no substrate is to be disposed during processing. Method 300 then ends with the carrier backside being treated at operation 350 to have the desired emissivity. In the exemplary embodiments where a high emissivity is desired, backside treatment is performed in a manner similar to that performed at operation 325, and potentially simultaneously with operation 325, since the bulk material had a relatively low emissivity ε₀.

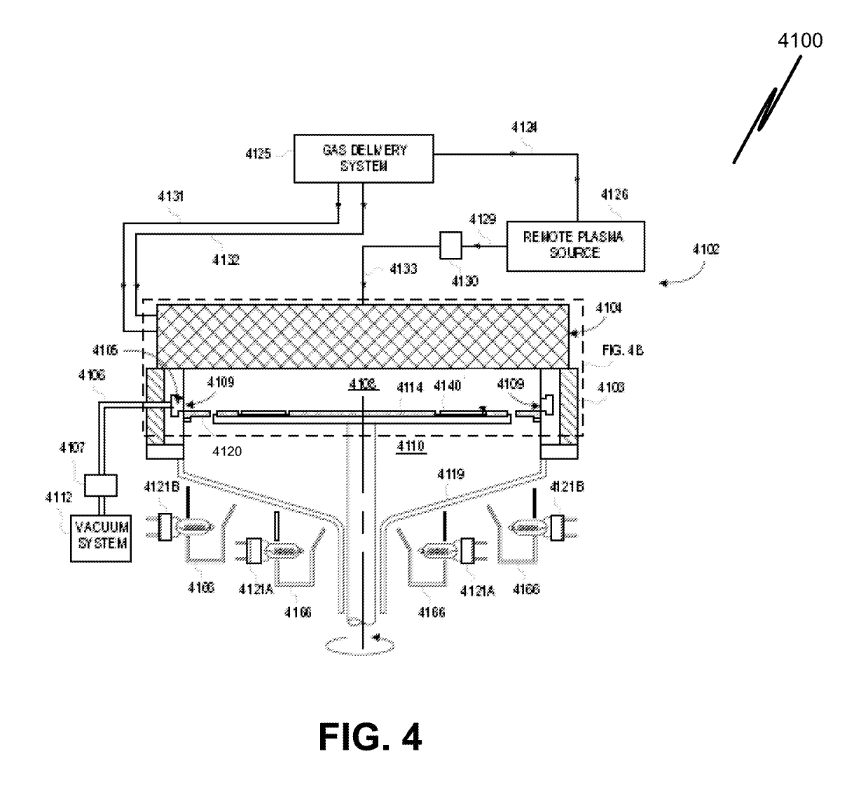

FIG. 4 depicts a schematic cross-sectional view of an MOCVD chamber which can be utilized in embodiments of the invention. Exemplary systems and chambers that may be adapted to practice the present invention are described in U.S. patent application Ser. No. 11/404,516, filed on Apr. 14, 2006, and Ser. No. 11/429,022, filed on May 5, 2006.

The MOCVD apparatus 4100 shown includes a chamber 4102, a gas delivery system 4125, a remote plasma source 4126, and a vacuum system 4112. The chamber 4102 includes a chamber body 4103 that encloses a processing volume 4108. A showerhead assembly 4104 is disposed at one end of the processing volume 4108, and a substrate carrier 4114 is disposed at the other end of the processing volume 4108. A lower dome 4119 is disposed at one end of a lower volume 4110, and the substrate carrier 4114 is disposed at the other end of the lower volume 4110. An exhaust ring 4120 may be disposed around the periphery of the substrate carrier 4114 to help prevent deposition from occurring in the lower volume 4110 and also help direct exhaust gases from the chamber 4102 to exhaust ports 4109. The lower dome 4119 may be made of transparent material, such as high-purity quartz, to allow light to pass through for radiant heating of the substrates 4140. The radiant heating may be provided by a plurality of inner lamps 4121A and outer lamps 4121B disposed below the lower dome 4119, and reflectors 4166 may be used to help control chamber 4102 exposure to the radiant energy provided by inner and outer lamps 4121A, 4121B. Additional rings of lamps may also be used for finer temperature control of the substrates 4140.

In one embodiment, one or more temperature sensors, such as pyrometers (not shown), may be disposed within the showerhead assembly 4104 to measure substrate 4140 and substrate carrier 4114 temperatures, and the temperature data may be sent to a controller (not shown) which can adjust power to separate lamp zones to maintain a predetermined temperature profile across the substrate carrier 4114.

The inner and outer lamps 4121A, 4121B may heat the substrates 4140 to a temperature of about 400 degrees Celsius to about 1200 degrees Celsius. It is to be understood that the invention is not restricted to the use of arrays of inner and outer lamps 4121A, 4121B. Any suitable heating source may be utilized to ensure that the proper temperature is adequately applied to the chamber 4102 and substrates 4140 therein. For example, in another embodiment, the heating source may comprise resistive heating elements (not shown) which are in thermal contact with the substrate carrier 4114. In embodiments, the substrate carrier 4114 comprises regions of differing emissivity as described for the carrier 206.

A gas delivery system 4125 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 4102. Different gases, such as precursor gases, carrier gases, purge gases, cleaning/etching gases or others may be supplied from the gas delivery system 4125 to separate supply lines 4131, 4132, and 4133 to the showerhead assembly 4104. The supply lines 4131, 4132, and 4133 may include shut-off valves and mass flow controllers or other types of controllers to monitor and regulate or shut off the flow of gas in each line. Reaction of process source gases at or near the substrate 4140 surface may deposit various metal nitride layers upon the substrate 4140, including GaN, aluminum nitride (AlN), and indium nitride (InN). Multiple metals may also be utilized for the deposition of other compound films such as AlGaN and/or InGaN. Additionally, dopants, such as silicon (Si) or magnesium (Mg), may be added to the films. The films may be doped by adding small amounts of dopant gases during the deposition process. For silicon doping of epitaxial layers, silane (SiH₄) or disilane (Si₂H₆) gases may be used, for example, and a dopant gas may include Bis(cyclopentadienyl)magnesium (Cp₂Mg or (C₅H₅)₂Mg) for magnesium doping.

A conduit 4129 may receive cleaning/etching gases from a remote plasma source 4126. The remote plasma source 4126 may receive gases from the gas delivery system 4125 via supply line 4124, and a valve 4130 may be disposed between the showerhead assembly 4104 and remote plasma source 4126. The valve 4130 may be opened to allow a cleaning and/or etching gas or plasma to flow into the showerhead assembly 4104 via supply line 4133 which may be adapted to function as a conduit for a plasma. In another embodiment, MOCVD apparatus 4100 may not include remote plasma source 4126 and cleaning/etching gases may be delivered from gas delivery system 4125 for non-plasma cleaning and/or etching using alternate supply line configurations to showerhead assembly 4104.

The remote plasma source 4126 may be a radio frequency or microwave plasma source adapted for chamber 4102 cleaning and/or substrate 4140 etching. Cleaning and/or etching gas may be supplied to the remote plasma source 4126 via supply line 4124 to produce plasma species which may be sent via conduit 4129 and supply line 4133 for dispersion through showerhead assembly 4104 into chamber 4102. Gases for a cleaning application may include fluorine, chlorine or other reactive elements.

In another embodiment, the gas delivery system 4125 and remote plasma source 4126 may be suitably adapted so that precursor gases may be supplied to the remote plasma source 4126 to produce plasma species which may be sent through showerhead assembly 4104 to deposit CVD layers, such as III-V films, for example, on substrates 4140.

A purge gas (e.g., nitrogen) may be delivered into the chamber 4102 from the showerhead assembly 4104 and/or from inlet ports or tubes (not shown) disposed below the substrate carrier 4114 and near the bottom of the chamber body 4103. The purge gas enters the lower volume 4110 of the chamber 4102 and flows upwards past the substrate carrier 4114 and exhaust ring 4120 and into multiple exhaust ports 4109 which are disposed around an annular exhaust channel 4105. An exhaust conduit 4106 connects the annular exhaust channel 4105 to a vacuum system 4112 which includes a vacuum pump (not shown). The chamber 4102 pressure may be controlled using a valve system 4107 which controls the rate at which the exhaust gases are drawn from the annular exhaust channel 4105.

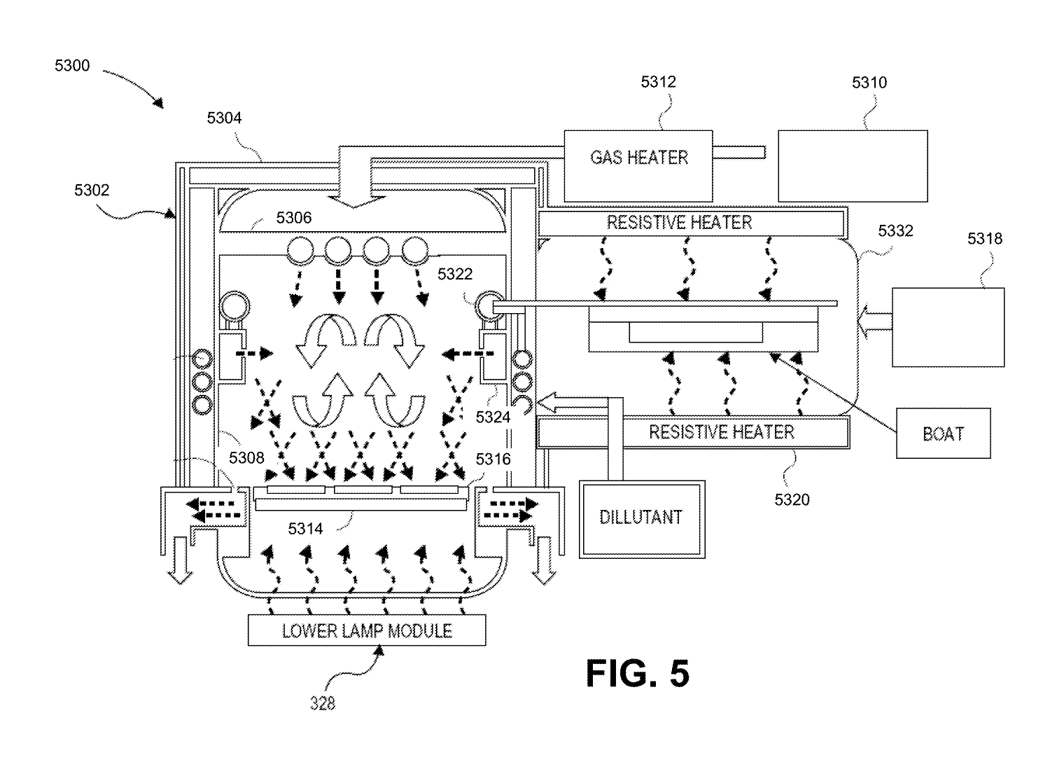

FIG. 5 is a schematic cross-sectional view of an HVPE apparatus 5300 which may incorporate a carrier having regions with differing emissivity coefficients, in accordance with an embodiment of the present invention. The apparatus includes a chamber 5302 enclosed by a lid 5304. Processing gas from a first gas source 5310 is delivered to the chamber 5302 through a gas distribution showerhead 5306. In one embodiment, the gas source 5310 may comprise a nitrogen containing compound. In another embodiment, the gas source 5310 may comprise ammonia. In one embodiment, an inert gas such as helium or diatomic nitrogen may be introduced as well either through the gas distribution showerhead 5306 or through the walls 5308 of the chamber 5302. An energy source 5312 may be disposed between the gas source 5310 and the gas distribution showerhead 5306. In one embodiment, the energy source 5312 may comprise a heater. The energy source 5312 may break up the gas from the gas source 5310, such as ammonia, so that the nitrogen from the nitrogen containing gas is more reactive.

To react with the gas from the first source 5310, precursor material may be delivered from one or more second sources 5318. The precursor may be delivered to the chamber 5302 by flowing a reactive gas over and/or through the precursor in the precursor source 5318. In one embodiment, the reactive gas may comprise a chlorine containing gas such as diatomic chlorine. The chlorine containing gas may react with the precursor source to form a chloride. In order to increase the effectiveness of the chlorine containing gas to react with the precursor, the chlorine containing gas may snake through the boat area in the chamber 5332 and be heated with the resistive heater 5320. By increasing the residence time that the chlorine containing gas is snaked through the chamber 5332, the temperature of the chlorine containing gas may be controlled. By increasing the temperature of the chlorine containing gas, the chlorine may react with the precursor faster. In other words, the temperature is a catalyst to the reaction between the chlorine and the precursor.

In order to increase the reactiveness of the precursor, the precursor may be heated by a resistive heater 5320 within the second chamber 5332 in a boat. The chloride reaction product may then be delivered to the chamber 5302. The reactive chloride product first enters a tube 5322 where it evenly distributes within the tube 5322. The tube 5322 is connected to another tube 5324. The chloride reaction product enters the second tube 5324 after it has been evenly distributed within the first tube 5322. The chloride reaction product then enters into the chamber 5302 where it mixes with the nitrogen containing gas to form a nitride layer on the substrate 5316 that is disposed on the carrier 5314. In one embodiment, the carrier 5314 may comprise regions of differing emissivity as described for the carrier 206. The nitride layer may comprise gallium nitride for example. The other reaction products, such as nitrogen and chlorine, are exhausted through an exhaust 5326.

The MOCVD apparatus 4100, HVPE apparatus 5300, or a deposition apparatus employing any alternative technology known in the art may be used in a processing system such as a cluster tool comprising multiple chambers that perform various processing steps that are used to form an electronic device. The cluster tool may be any platform known in the art that is capable of adaptively controlling a plurality of process modules simultaneously. Exemplary embodiments include an Opus™ AdvantEdge™ system or a Centura™ system, both commercially available from Applied Materials, Inc. of Santa Clara, Calif. Alternatively, the MOCVD apparatus 4100, HVPE apparatus 5300, or an alternative technology deposition apparatus (e.g., a HVPE chamber) may be adapted into an in-line processing apparatus.

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration. Accordingly, the specification and drawings are to be regarded in an illustrative sense rather than a restrictive sense.

What is claimed is:

1. A substrate carrier for supporting a substrate during a deposition process, comprising:
a first carrier surface upon which the substrate is to be disposed, the first carrier surface having a first emissivity coefficient;
a second carrier surface adjacent to the first carrier surface, the second carrier surface having a second emissivity coefficient, lower than first emissivity coefficient.

2. The substrate carrier of claim 1, wherein the difference between the first and second emissivity coefficients is at least 0.2 as measured at a same reference temperature.

3. The substrate carrier of claim 1, wherein the first carrier surface roughness is greater than that of the second carrier surface.

4. The substrate carrier of claim 3, wherein the second carrier surface comprises a same material than the second carrier surface.

5. The substrate carrier of claim 3, wherein the second carrier surface comprises a different material than the second carrier surface.

6. The substrate carrier of claim 5, wherein the carrier comprises a bulk material and the second carrier surface comprises a first coating disposed over the bulk material.

7. The substrate carrier of claim 6, wherein the first coating has an emissivity coefficient less than or equal to 0.7 at 1100° C.

8. The substrate carrier of claim 6, wherein the first coating comprises a material selected from the group consisting of: zirconium oxide, mullite (Al₆Si₂O₁₃), macor, cerium oxide, zirconium oxide, polished tungsten, nickel-chromium (Ni—Cr), nickel-chromium-iron (Ni—Cr—Fe), polished molybdenum, and aluminum oxide.

9. The substrate carrier of claim 6, wherein the bulk material comprises silicon carbide, tungsten, or molybdenum.

10. The substrate carrier of claim 9, wherein first carrier surface comprises silicon carbide, tungsten, or molybdenum.

11. The substrate carrier of claim 6, wherein the first carrier surface comprises a second coating material disposed over the bulk material, the second coating material having a higher emissivity coefficient than that of the bulk material.

12. The substrate carrier of claim 1, wherein the second carrier surface comprises a material other than group III-V materials.

13. The substrate carrier of claim 1, wherein at least a portion of the first carrier surface area is recessed below the second carrier surface to form a pocket in which the substrate is to be disposed.

14. The substrate carrier of claim 1, wherein the first carrier surface includes a second portion extending a distance away from pocket to separate the second region from the substrate.

15. The substrate carrier of claim 1, further comprising a back surface, opposite the first and second carrier surfaces, wherein the back surface has a third emissivity coefficient which is greater than the second emissivity coefficient.

16. The substrate carrier of claim 15, wherein the third emissivity coefficient is equal to the first emissivity coefficient.

17. A system for epitaxially growing a semiconductor stack on a substrate, the system comprising:
a deposition chamber coupled with a group III source gas, a nitrogen source gas, and a silicon source gas; and
a substrate carrier for supporting a substrate during a deposition process, the substrate carrier further comprising:
a first carrier surface upon which the substrate is to be disposed, the first carrier surface having a first emissivity coefficient; and
a second carrier surface adjacent to the first carrier surface, the second carrier surface having a second emissivity coefficient, lower than first emissivity coefficient.

18. The system of claim 17, wherein the first carrier surface comprises a different material than the second carrier surface or the first carrier surface comprises the same material as the second carrier surface with the first carrier surface being rougher than the second carrier surface.

19. A method of forming a substrate carrier for supporting a substrate during a deposition process, the method comprising:
processing a bulk material to have a first emissivity coefficient in a first region of the carrier upon which the substrate is to be disposed; and
processing the bulk material to have a second emissivity coefficient in a second region of the carrier, the second emissivity coefficient being lower than the first emissivity coefficient.

20. The method of claim 19, wherein processing the bulk material to have the second emissivity coefficient further comprises either polishing the bulk material or coating the bulk material with a coating material different than the bulk material.
